(19) United States
(12) Patent Application Publication
(10) Pub. No.: US 2026/0239719 A1
(43) Pub. Date: Aug. 13, 2026

(54) SEMICONDUCTOR DEVICES WITH FIELD RELIEF LAYERS AND INTEGRATED METHODS OF FABRICATION THEREOF

(71) Applicant: TEXAS INSTRUMENTS INCORPORATED, Dallas, TX (US)

(72) Inventors: Jackson Bauer, Rowlett, TX (US); Casey Hopper, Richardson, TX (US); Zeshaan Shamsi, Rockwall, TX (US); Archana Venugopal, Mountain View, CA (US)

(21) Appl. No.: 19/052,562

(22) Filed: Feb. 13, 2025

(51) Int. Cl. H10D 84/01; H10D 62/10; H10D 64/27; H10D 84/83

(52) U.S. Cl. CPC H10D 84/0151; H10D 62/116; H10D 64/516; H10D 84/0144; H10D 84/835

(57) ABSTRACT

Semiconductor devices and fabrication methods thereof are described. For example, a method of fabricating a semiconductor device includes forming a first field relief layer on a first surface of a semiconductor layer, wherein the first field relief layer is a step-oxide field relief layer formed from a first oxide layer, and the first oxide layer is formed via a local oxidation of silicon (LOCOS) process. The method also includes forming a first drain region, a first source region, and a first gate stack, wherein the first drain region is proximate to a first end of the first field relief layer, the first source region is proximate to a second end of the first field relief layer, and the first gate stack is between the first drain region and the first source region and partially over the first field relief layer.

### TECHNICAL FIELD

The present disclosure relates to the field of semiconductor devices, and more particularly, but not exclusively, to laterally diffused metal oxide semiconductor (LDMOS) transistors.

### BACKGROUND

LDMOS devices are field-effect transistors (FETs) that are utilized in high power applications. In an LDMOS device, the drain and source have a relatively large spacing between them, as compared with MOS devices for other applications, and lateral diffusions are used to produce a well-controlled channel region under the gate. The operational performance of LDMOS devices is generally affected by parameters including, for example, a specific on-resistance (Rsp) and a breakdown voltage (BV). A desirable approach for LDMOS devices is to decrease Rsp and increase BV, or at least to improve one parameter without adversely affecting the other parameter in a significant manner.

### SUMMARY

The present disclosure describes semiconductor devices with field relief layers and integrated methods of fabrication thereof. This summary is not an extensive overview of the disclosure. Rather, a purpose of the summary is to present some examples of the present disclosure in a simplified form as a prelude to a more detailed description that is presented later.

In one example, a method of fabricating a semiconductor device includes forming a first field relief layer on a first surface of a semiconductor layer, wherein the first field relief layer is a step-oxide field relief layer formed from a first oxide layer, and the first oxide layer is formed via a local oxidation of silicon (LOCOS) process. The method also includes forming a first drain region, a first source region, and a first gate stack, wherein the first drain region is proximate to a first end of the first field relief layer, the first source region is proximate to a second end of the first field relief layer, and the first gate stack is between the first drain region and the first source region and partially over the first field relief layer.

In another example, a method of fabricating a semiconductor device includes forming a first transistor. The first transistor is formed to include: (i) a first field relief layer on a first surface of a semiconductor layer, wherein the first field relief layer is a step-oxide field relief layer formed from a first local oxidation of silicon (LOCOS) layer, (ii) a first drain region, (iii) a first source region, and (iv) a first gate stack, wherein the first drain region is proximate to a first end of the first field relief layer, the first source region is proximate to a second end of the first field relief layer, and the first gate stack is between the first drain region and the first source region and partially over the first field relief layer. The method also includes forming a second transistor. The second transistor is formed to include: (i) a second field relief layer on a second surface of the semiconductor layer, wherein the second field relief layer is a second LOCOS field relief layer formed via the same LOCOS process as the first LOCOS layer, (ii) a second drain region, (iii) a second source region, and (iv) a second gate stack, wherein the second drain region is proximate to a first end of the second field relief layer, the second source region is proximate to a second end of the second field relief layer, and the second gate stack is between the second drain region and the second source region and partially over the second field relief layer.

In an additional example, a semiconductor device includes a semiconductor layer, a first transistor, and a second transistor. The first transistor is disposed in a first region of the semiconductor layer and includes: a first field relief layer; a first drain region disposed proximate to a first end of the first field relief layer; a first source region disposed proximate to a second end of the first field relief layer; and a first gate stack including a first gate electrode and a first gate dielectric layer. The first gate stack is disposed between the first drain region and the first source region and partially over the first field relief layer. The second transistor is disposed in a second region of the semiconductor layer different than the first region, and the second transistor includes a second gate dielectric layer, wherein the first gate dielectric layer is recessed relative to the second gate dielectric layer.

### BRIEF DESCRIPTION OF THE DRAWINGS

FIG. 1 is a cross-sectional view of a semiconductor device with field relief layers in accordance with an example of the present disclosure;

FIGS. 2A-2J are cross-sectional views of a process flow for forming a semiconductor device with field relief layers in accordance with the example of FIG. 1;

FIG. 3 is a cross-sectional view of a semiconductor device with field relief layers in accordance with another example of the present disclosure; and

FIGS. 4A-4J are cross-sectional views of a process flow for forming a semiconductor device with an asymmetric field relief layer in accordance with the example of FIG. 3.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about” or “approximately,” preceding a value mean +/−10-20 percent (%) of the stated value. The terms “substantially” or “substantially equal” means values within ±2.5% of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

As mentioned, the operational performance of an LDMOS device is generally affected by a tradeoff between a specific on-resistance (Rsp) parameter and a breakdown voltage (BV) parameter. For example, approaches that seek to achieve the advantage of a higher BV by increasing the body area of the device consequently lead to the disadvantage of a higher Rsp. Similarly, approaches that seek to decrease Rsp generally come at the cost of decreasing the BV rating. Accordingly, desirable approaches for LDMOS devices that effectively manage this tradeoff provide technical advantages.

LDMOS devices, and other power devices, may utilize field relief regions for tuning the Rsp and BV parameters. Such field relief regions, which typically include one or more dielectric materials disposed (at least partially) below a gate stack, may take different forms. Examples of field relief regions include: (i) a shallow trench isolation (STI) layer which is a field relief region formed in a trench below a surface of a semiconductor layer of the LDMOS device; (ii) a step gate (e.g., a step dielectric, a step oxide) layer which is a field relief region formed above a surface of the semiconductor layer; and (iii) a local oxidation of silicon (LOCOS) layer which is a field relief region formed at least partially in the semiconductor layer (e.g., partially above and partially below a surface of the semiconductor layer).

While each form of field relief region provides technical advantages over the absence of a field relief region in a device, e.g., each form of field relief, relative to the others, results in comparatively different improvements in the Rsp and BV parameters of the device. For example, while a LOCOS layer improves one or more of the device parameters by avoiding the relatively sharp dielectric sidewall transitions inherent in an STI layer, a step gate layer improves over a LOCOS layer in that there are no transitions in the semiconductor layer, e.g., a direct path for the channel formed between the source and drain.

Nonetheless, there may be technical advantages for some components on a die to have one form of field relief, while other components on the die have a different form of field relief. Utilizing different forms of field relief on the same die, however, can introduce a burdensome number of additional, often duplicate, process steps. For example, using typical process flows, transistors having different forms of field relief regions may require separate mask setups followed by separate patterning and etching process steps increasing cost and increasing the potential for device defects.

To address the above and other technical challenges in LDMOS and other power devices, examples of the present disclosure describe semiconductor devices with field relief layers and integrated methods of fabrication thereof. While examples of the disclosure may be expected to provide improvements such as may be described herein, no particular result is a requirement of the present invention unless explicitly recited in a particular claim.

In one example, a method of fabricating a semiconductor device includes forming a first field relief layer on a first surface of a semiconductor layer. The first field relief layer is a step-oxide field relief layer formed from a first oxide layer, and the first oxide layer is formed via a local oxidation of silicon (LOCOS) process. The method also includes forming a first drain region, a first source region, and a first gate stack. The first drain region is proximate to a first end of the first field relief layer, while the first source region is proximate to a second end of the first field relief layer. The first gate stack is formed between the first drain region and the first source region and partially over the first field relief layer.

In some examples, the method includes forming a second field relief layer on a second surface of the semiconductor layer, wherein the second field relief layer is formed concurrently with the first oxide layer via the LOCOS process. The method also includes forming a second drain region, a second source region, and a second gate stack, the second drain region being proximate to a first end of the second field relief layer, the second source region being proximate to a second end of the second field relief layer, and the second gate stack being between the second drain region and the second source region and partially over the second field relief layer.

In other examples, the first surface of the semiconductor layer is recessed relative to the second surface of the semiconductor layer as a result of the LOCOS process. In yet other examples, the first source region, the first drain region, the first gate stack, and the first field relief layer are formed in a recessed region, and the second source region, the second drain region, the second gate stack, and the second field relief layer are formed outside the recessed region.

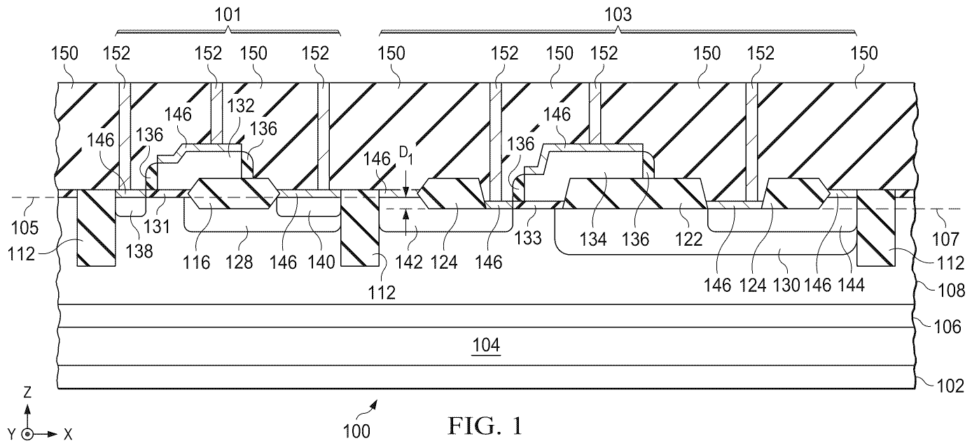

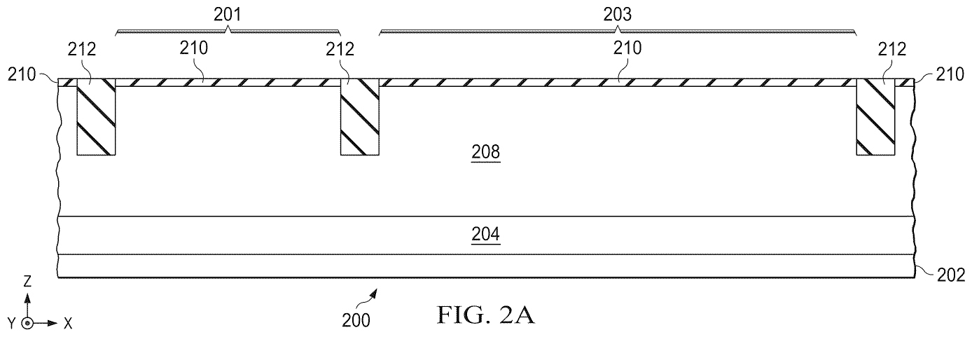

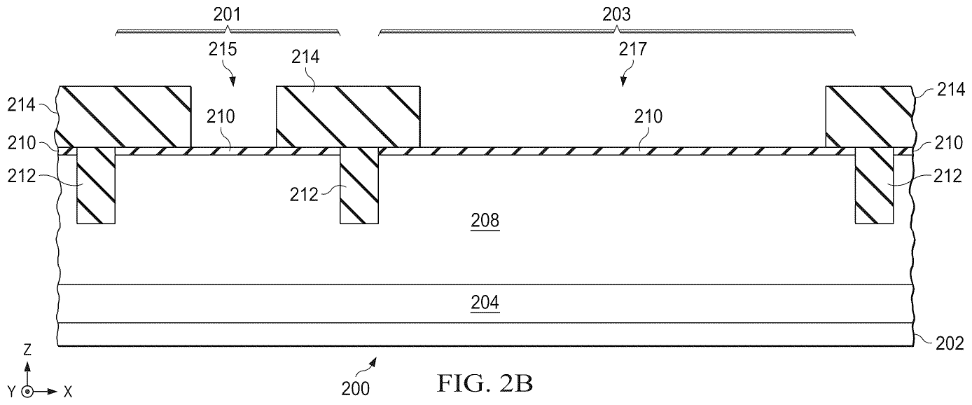

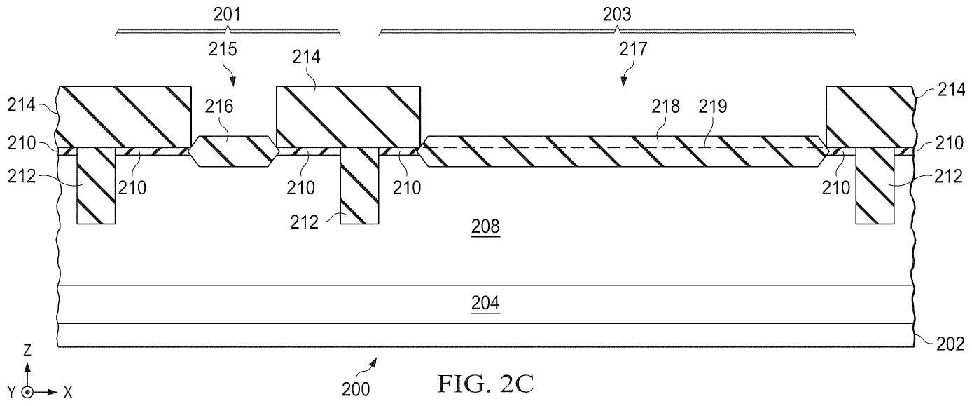

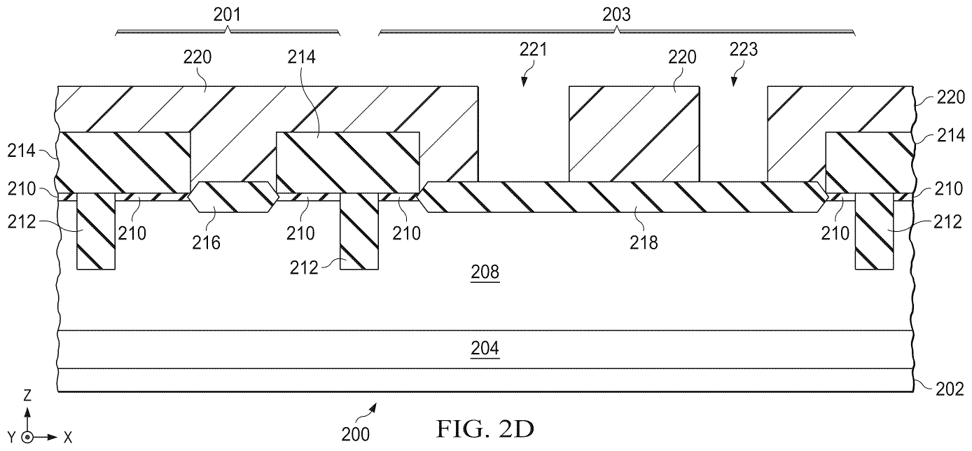

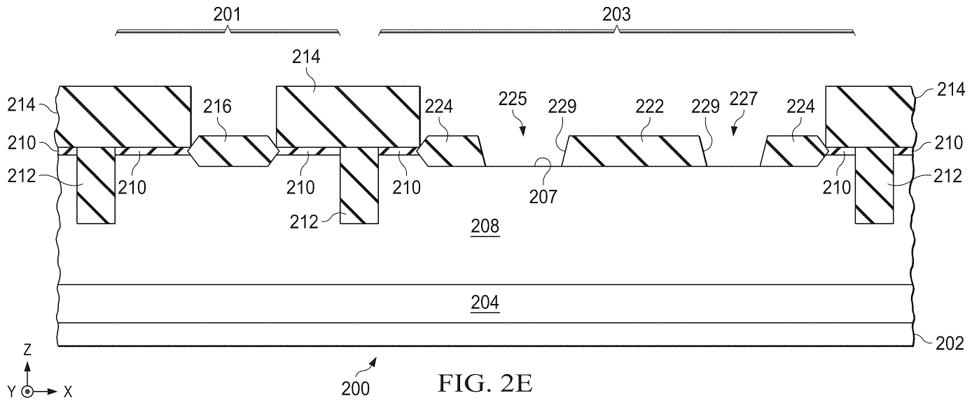

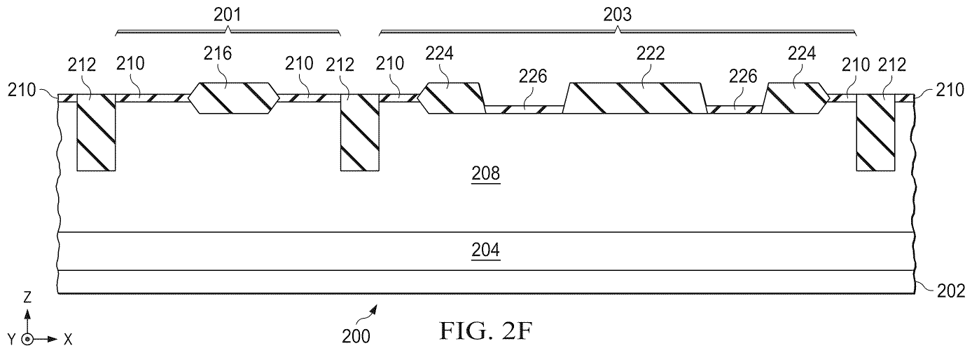

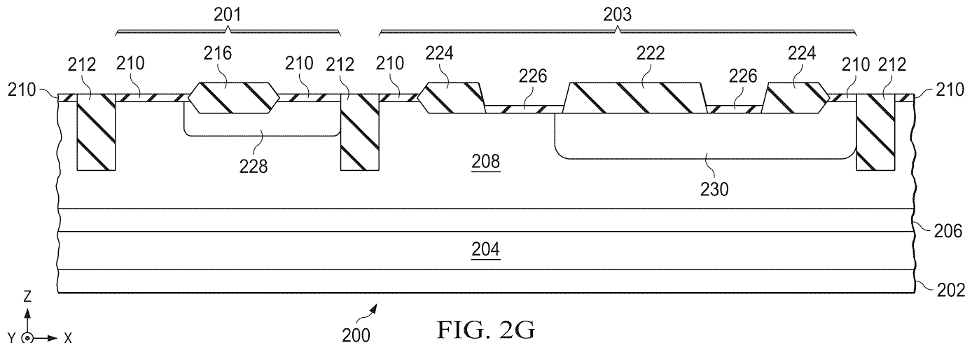

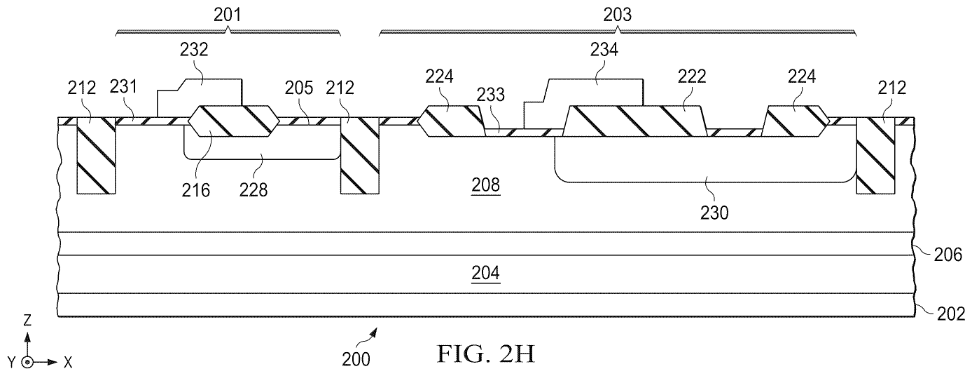

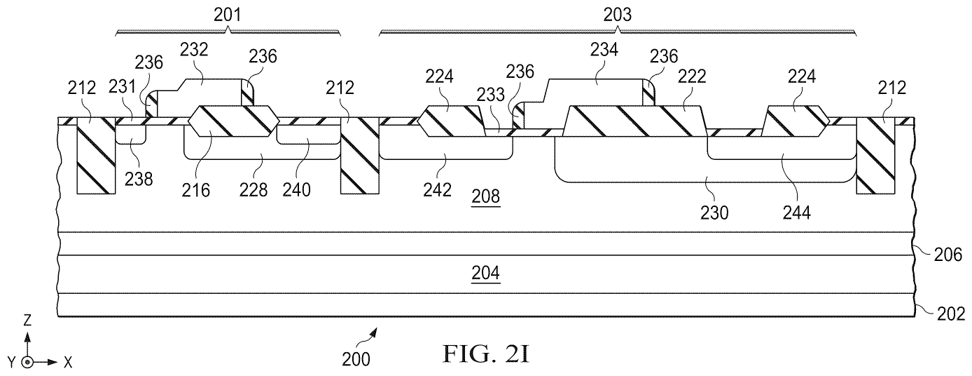

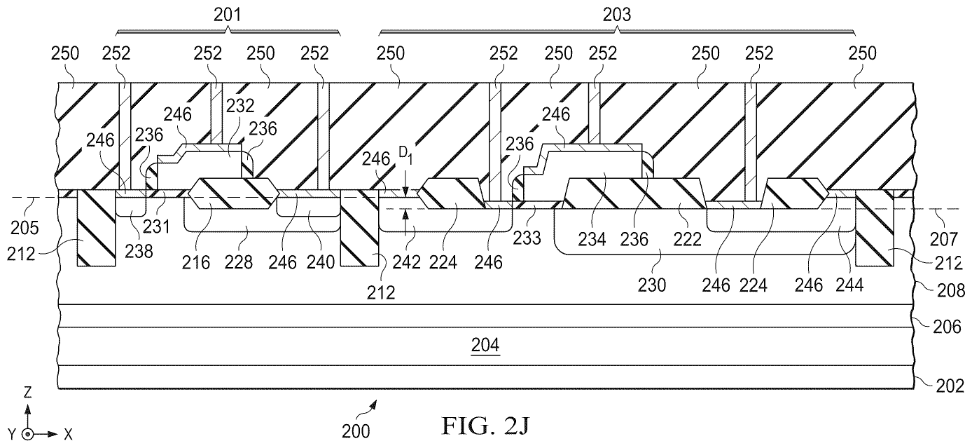

In some examples, e.g., as will be described herein in the context of FIGS. 1 and 2A through 2J, forming the first field relief layer includes forming a thin oxide layer, relative to a thickness of the first oxide layer, on a second surface of the semiconductor layer, the thin oxide layer being between a pair of isolation regions. Then, a first portion and a second portion of a nitride layer is formed, the first portion of the nitride layer being formed over a first one of the pair of isolation regions and a first portion of the thin oxide layer, and the second portion of the nitride layer being formed over a second one of the pair of isolation regions and a second portion of the thin oxide layer. An opening is formed between the first portion of the nitride layer and the second portion of the nitride layer. The method further includes thermally growing the first oxide layer in the opening, the first oxide layer extending to the first surface of the semiconductor layer, wherein the first surface of the semiconductor layer being recessed relative to the second surface of the semiconductor layer as a result of the LOCOS process.

In additional examples, forming the first field relief layer further includes etching the first oxide layer substantially to the first surface of the semiconductor layer, using a first mask, to form a middle portion of the first oxide layer and two end portions of the first oxide layer separated from and on opposite sides of the middle portion, the middle portion being the first field relief layer. The two end portions of the first oxide layer have respective bird's beak profiles separated from respective ones of the pair of isolation regions.

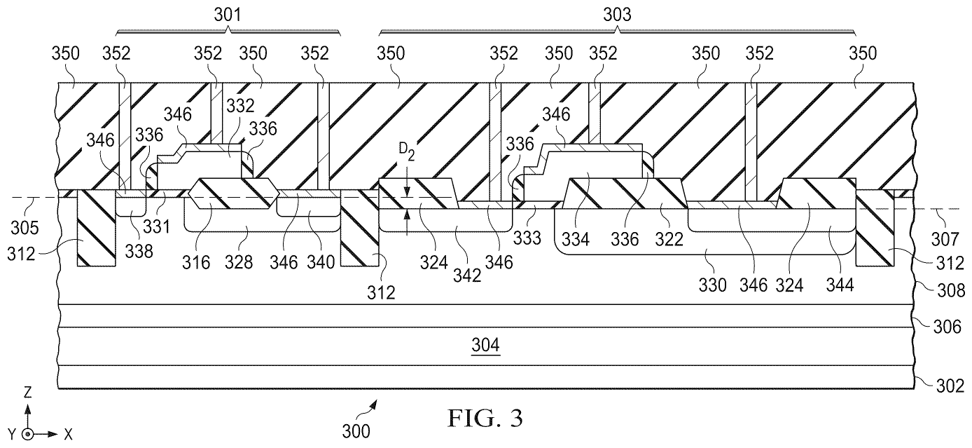

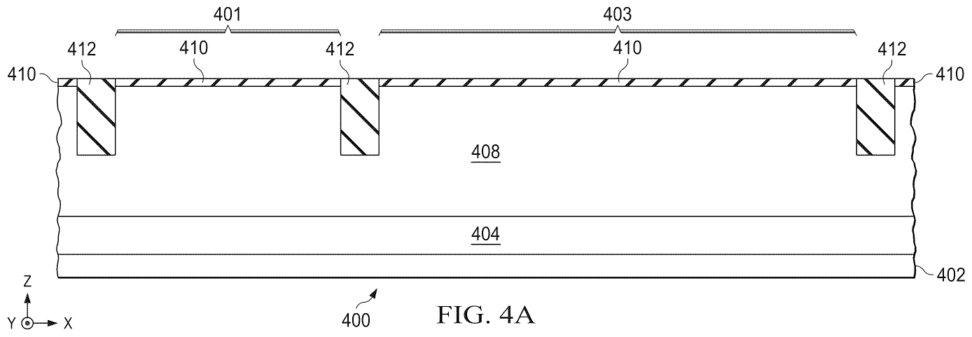

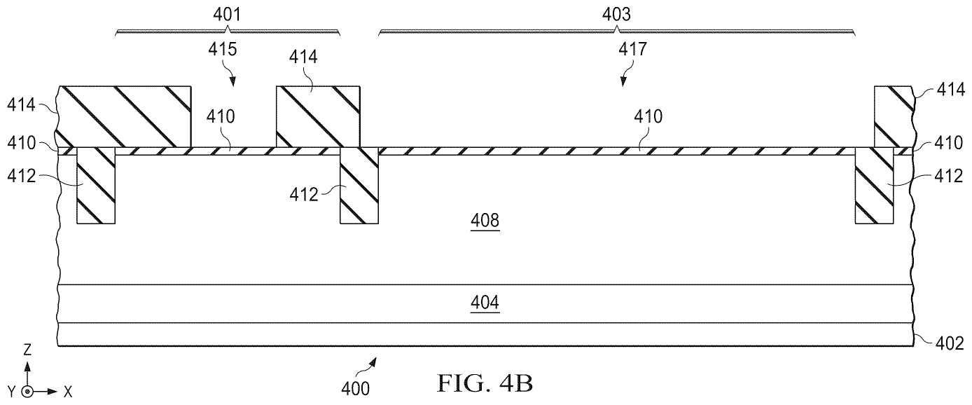

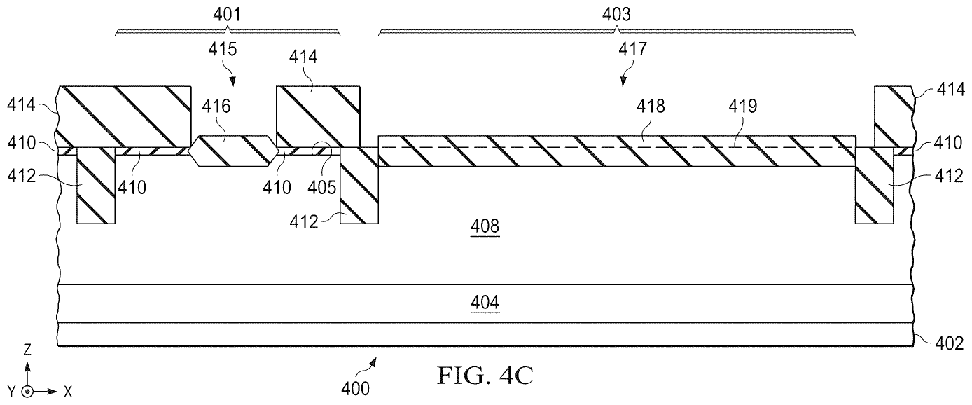

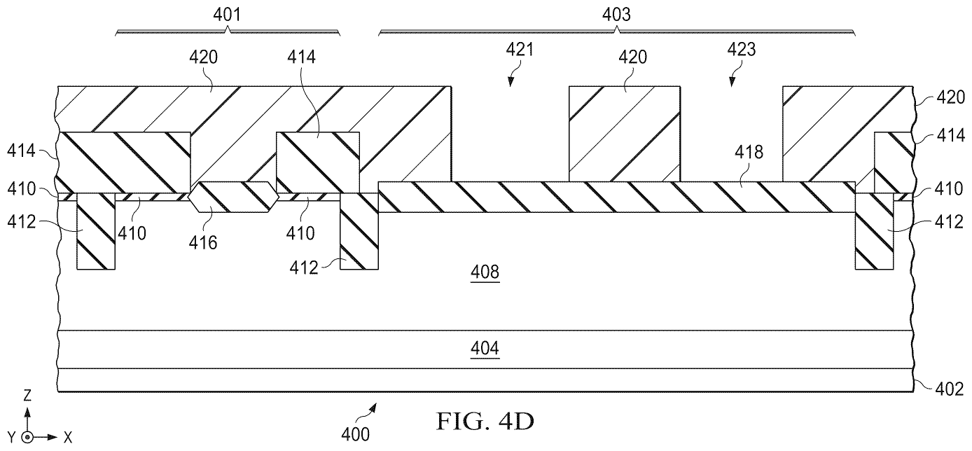

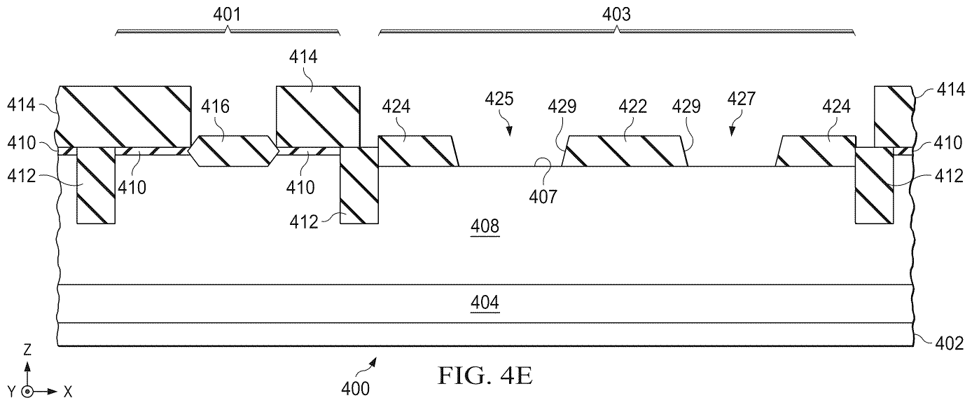

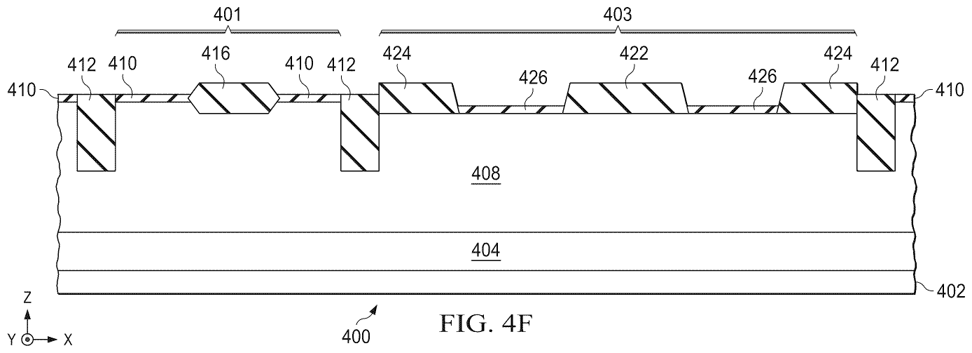

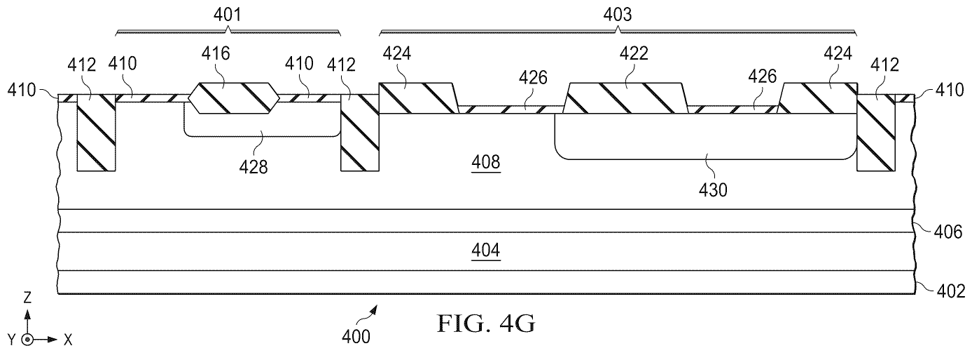

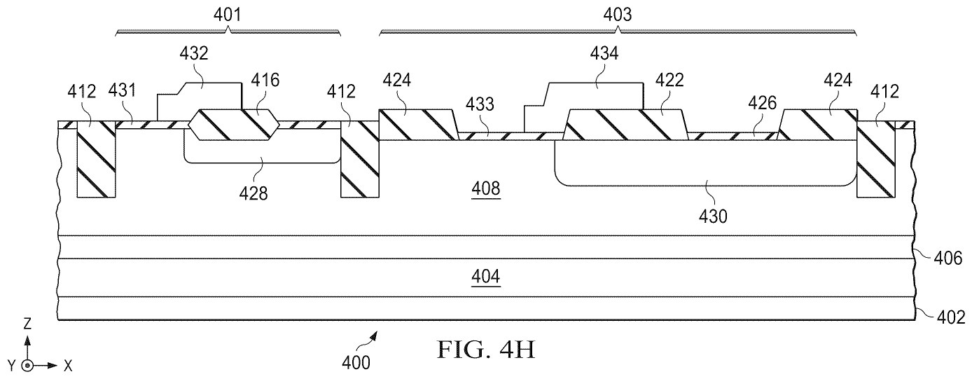

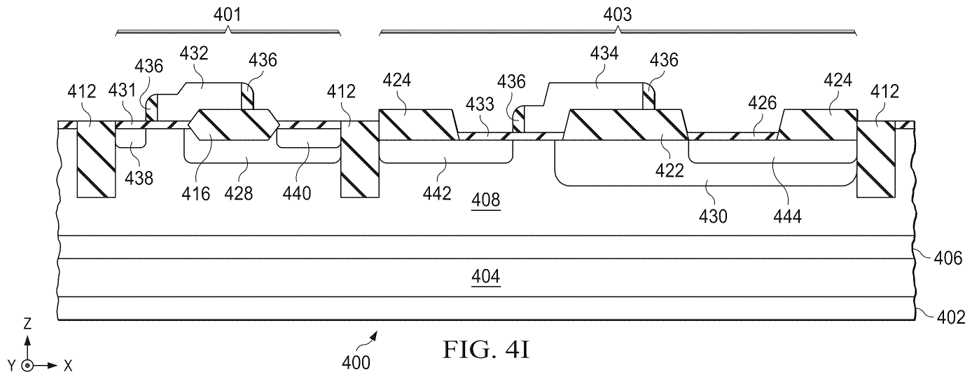

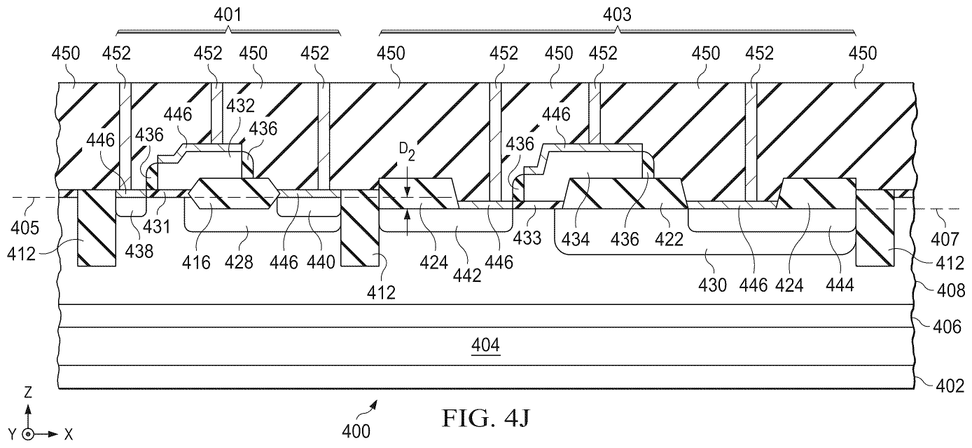

In other examples, e.g., as will be described herein in the context of FIGS. 3 and 4A through 4J, forming the first field relief layer further includes forming a thin oxide layer, relative to a thickness of the first oxide layer, on a second surface of the semiconductor layer, the thin oxide layer being between a pair of isolation regions. Then, a first portion and a second portion of a nitride layer is formed, the first portion of the nitride layer being formed partially over a first one of the pair of isolation regions, and the second portion of the nitride layer being formed partially over a second one of the pair of isolation regions. An opening is formed between the first portion of the nitride layer and the second portion of the nitride layer. The method further includes thermally growing the first oxide layer in the opening, the first oxide layer extending to the first surface of the semiconductor layer, wherein the first surface of the semiconductor layer being recessed relative to the second surface of the semiconductor layer as a result of the LOCOS process.

In additional examples, forming the first field relief layer further includes etching the first oxide layer substantially to the first surface of the semiconductor layer, using a first mask, to form a middle portion of the first oxide layer and two end portions of the first oxide layer separated from and on opposite sides of the middle portion, the middle portion being the first field relief layer. The two end portions of the first oxide layer each abut respective ones of the pair of isolation regions.

In another example, a method of fabricating a semiconductor device includes forming a first transistor including: (i) a first field relief layer on a first surface of a semiconductor layer, the first field relief layer being a step-oxide field relief layer formed from a first local oxidation of silicon (LOCOS) layer, (ii) a first drain region, (iii) a first source region, and (iv) a first gate stack, the first drain region being proximate to a first end of the first field relief layer, the first source region being proximate to a second end of the first field relief layer, and the first gate stack being between the first drain region and the first source region and partially over the first field relief layer. The method further includes forming a second transistor including: (i) a second field relief layer on a second surface of the semiconductor layer, the second field relief layer being a second LOCOS field relief layer formed via the same LOCOS process as the first LOCOS layer, (ii) a second drain region, (iii) a second source region, and (iv) a second gate stack, the second drain region being proximate to a first end of the second field relief layer, the second source region being proximate to a second end of the second field relief layer, and the second gate stack being between the second drain region and the second source region and partially over the second field relief layer.

In yet another example, a semiconductor device includes a semiconductor layer, a first transistor, and a second transistor. The first transistor is disposed in a first region of the semiconductor layer. The first transistor includes a first field relief layer, a first drain region disposed proximate to a first end of the first field relief layer, a first source region disposed proximate to a second end of the first field relief layer, and a first gate stack including a first gate electrode and a first gate dielectric layer, the first gate stack disposed between the first drain region and the first source region and partially over the first field relief layer. The second transistor is disposed in a second region of the semiconductor layer different than the first region, the second transistor including a second gate dielectric layer, the first gate dielectric layer being recessed relative to the second gate dielectric layer.

In further examples, the second transistor includes a second field relief layer having a first portion disposed partially in the semiconductor layer and a second portion disposed partially above the semiconductor layer, a second drain region disposed proximate to a first end of the second field relief layer, a second source region disposed proximate to a second end of the second field relief layer, and a second gate stack including a second gate electrode and the second gate dielectric layer, the second gate stack disposed between the second drain region and the second source region and partially over the second field relief layer.

In other examples, the semiconductor device further includes a pair of isolation regions including a first isolation region disposed on a first end of the first region and a second isolation region disposed on a second end of the first region.

In other examples, the first transistor includes a first oxide region separated from the first isolation region and the first end of the first field relief layer, and a second oxide region separated from the second isolation region and the second end of the first field relief layer.

In yet other examples, the first transistor structure includes a first oxide region abutting the first isolation region and separated from the first end of the first field relief layer, and a second oxide region abutting the second isolation region and separated from the second end of the first field relief layer.

The first field relief layer, in some examples, includes one or more substantially straight sidewalls, and the second field relief layer includes opposing ends having bird's beak profiles.

In some examples, the first field relief layer and the second field relief layer are at least partially concurrently formed. In some other examples, the first field relief layer has a width, defined along a direction between the first source region and the first drain region, less than a width of the first region. Still further, the first field relief layer is a step-oxide field relief layer in some examples.

Referring now to FIG. 1, a semiconductor device 100 is shown. The semiconductor device 100 is illustrated in an example three-dimensional space with a first direction X, a perpendicular (orthogonal) second direction Y, and a third direction Z that is perpendicular (orthogonal) to the respective first and second directions X and Y. Structures or features along any two of these directions are orthogonal to one another.

While semiconductor device 100 is shown as including two LDMOS transistors, e.g., an LDMOS transistor 101 and an LDMOS transistor 103, additional transistors (e.g., LDMOS and/or other transistor types) and/or other components that are not expressly shown may be integrated as part of semiconductor device 100 in various other examples. Also, while the LDMOS transistors in FIG. 1 are illustrated as n-channel LDMOS transistors, in one or more alternative examples, one or more p-channel LDMOS transistors can be formed when n-type regions are substituted by p-type regions and p-type regions are substituted by n-type regions. As used herein, a region, layer, structure, or the like, referred to as being of “a first conductivity type” can be one of a p-type or an n-type, while a region, layer, structure, or the like, referred to as being of “an opposite second conductivity type” can be the other of a p-type or an n-type.

As shown, the semiconductor device 100 includes a semiconductor substrate 102, a first buried layer 104 disposed on the semiconductor substrate 102, a second buried layer 106 disposed on the first buried layer 104, and a semiconductor layer 108 disposed on the second buried layer 106. In some examples, the semiconductor layer 108 can be formed by an epitaxial process, and thus can be referred to as an epitaxial or “epi” layer 108. In the FIG. 1 example, the semiconductor substrate 102 is a p-type substrate, the second buried layer 106 is p-type buried layer (PBL 106), and the semiconductor layer 108 is a p-type semiconductor layer, while the first buried layer 104 is an n-type buried layer (NBL 104). In some examples, the PBL 106 has a dopant concentration greater than the semiconductor layer 108 and can be used to implement reduced surface field (RESURF) principles for safe operating area (SOA) improvement in the semiconductor device 100. While two buried layers, e.g., the NBL 104 and the PBL 106, are shown in FIG. 1, other examples may include one or the other of the buried layers, or no buried layers.

A plurality of isolation regions 112 are disposed in semiconductor layer 108. FIG. 1, being a cross-sectional view, illustrates each of LDMOS transistor 101 and LDMOS transistor 103 are disposed between a pair of the isolation regions 112 with LDMOS transistor 101 and LDMOS transistor 103 separated by a shared isolation region 112. The isolation regions 112 may laterally surround each of LDMOS transistor 101 and LDMOS transistor 103 in a top-down view (e.g., a layout view). In some examples, the isolation regions 112 are STI regions, while in other examples, the isolation regions 112 are deep trench (DT) regions, both STI and DT regions, or some combination thereof. Various other forms of component (e.g., transistor) isolation can be additionally or alternatively implemented in other examples.

As will be further described below in the context of FIGS. 2A-2J, corresponding elements of the LDMOS transistor 101 and the LDMOS transistor 103 (e.g., source regions, drain regions, gate stacks, field relief layers, etc.) are formed in an integrated (e.g., modular) manner. In this context, for example, integrated means that corresponding elements in the LDMOS transistors 101 and 103 are formed at the same (or substantially the same) time using the same process step(s). By way of example, a source region in the LDMOS transistor 101 and a source region in the LDMOS transistor 103 are formed at the same (or substantially the same) time using the same masking and implanting steps, a drain region in the LDMOS transistor 101 and a drain region in the LDMOS transistor 103 are formed at the same (or substantially the same) time using the same masking and implanting steps, and so on. Again, while FIG. 1 depicts only the LDMOS transistors 101 and 103, semiconductor device 100 can include one or more additional transistors and/or other components-wherein one or more corresponding elements of the one or more transistors and/or other components can be similarly formed in an integrated or modular manner along with the LDMOS transistors 101 and 103.

As further shown, LDMOS transistor 101 includes a first field relief layer 116. The first field relief layer 116 is formed via a local oxidation of silicon (LOCOS) process, thus also being referred to herein as a LOCOS layer 116. As will be described below in the context of FIGS. 2A-2J, a second field relief layer 122, which is part of the LDMOS transistor 103 in the form of a step dielectric (step gate) layer, and also referred to herein as a step oxide layer 122, is at least initially formed in an integrated manner via the same LOCOS process used to form the first field relief layer 116 (e.g., the LOCOS layer 116).

LDMOS transistor 101 also includes an n-type drain drift region 128 disposed in the semiconductor layer 108, an n-type source region 138, and an n-type drain region 140 disposed in the drain drift region 128. The first field relief layer 116 is disposed between the source region 138 and the drain region 140, partially above a first surface of the semiconductor layer 108 denoted by a dashed line 105 (also referred to as a first surface 105) and partially below the first surface 105 and in the drain drift region 128.

In some examples, although not expressly shown in FIG. 1, the LDMOS transistor 101 can also include a p-type body contact region adjacent the source region 138, both disposed in a deep p-type well (DPWELL). The DPWELL can be disposed in the semiconductor layer 108. A shallow p-type well (SPWELL) (not expressly shown) can also be disposed within the DPWELL. In such examples, the DPWELL can extend partially into the PBL 106. In some examples, the SPWELL has a dopant density higher than that of the semiconductor layer 108. When implemented, the SPWELL increases a base doping level of the semiconductor layer 108 to suppress a parasitic lateral NPN bipolar transistor formed by n-type source/p-type body region/n-type drain, which may limit high current operation for the LDMOS transistor 101 thus restricting its SOA.

The LDMOS transistor 101 further includes a gate stack. The gate stack includes a gate dielectric layer 131 disposed on a portion of the first surface 105 of the semiconductor layer 108. The gate stack further includes a gate electrode 132 disposed over the gate dielectric layer 131 and at least a portion of the first field relief layer 116. As shown in FIG. 1, the gate electrode 132 extends along the gate dielectric layer 131 and slopes upward in the Z direction along a first bird's beak portion of the first field relief layer 116 proximate to the source region 138 before terminating at an edge along a top non-sloped surface of the first field relief layer 116 (e.g., prior to reaching a second bird's beak portion of the first field relief layer 116 proximate to the drain region 140). In some examples, the edge of the gate electrode 132 above the top non-sloped surface of the first field relief layer 116 may terminate closer to the source region 138 or closer to the drain region 140 as compared to where it is shown terminating in FIG. 1.

In some examples, the gate electrode 132 includes a polysilicon material. In other examples, the gate electrode 132 includes a metal or other suitable material. A channel region may be considered to extend across a portion of the semiconductor layer 108 under the gate electrode 132 between the source region 138 and the drain region 140.

As further shown in FIG. 1, the LDMOS transistor 101 includes sidewall spacer structures 136 along the lateral sides of the gate electrode 132. The sidewall spacer structures 136 in one example include an oxide layer and a nitride layer (not expressly shown). In another example, a nitride-only (or oxide-only) sidewall spacer structure can be implemented.

The LDMOS transistor 101 also includes metal silicide layers 146 that respectively extend over the source region 138, the drain region 140, and the gate electrode 132. In addition, in some examples, the LDMOS transistor 101 includes a nitride etch stop layer (not expressly shown) that extends over portions of the metal silicide layers 146 and the sidewall spacer structures 136. The LDMOS transistor 101 can include a single or multilevel metallization structure (e.g., shared with the LDMOS transistor 103), with a pre-metal dielectric (PMD) layer 150 and conductive metal (e.g., tungsten) contacts 152, terminating on the respective metal silicide layers 146 for the source region 138, the drain region 140, and the gate electrode 132. In some examples, the metal silicide layers 146 can be formed from a Cobalt silicide (CoSiₓ) material.

With reference now to the LDMOS transistor 103, a second field relief layer 122 (e.g., also referred to as a step dielectric layer 122, a step gate layer 122, or a step oxide layer 122) is disposed, as shown in FIG. 1, on a second surface of the semiconductor layer 108 denoted by a dashed line 107 (also referred to as a second surface 107). The second surface 107 of the semiconductor layer 108 is recessed by a depth D₁ (in the Z direction) relative to the first surface 105 of the semiconductor layer 108. In some examples, the depth D₁ is in a range of approximately 20-100 nanometers (nm), e.g., approximately 50 nm.

As described above, and as will be further described below in the context of FIGS. 2A-2J, the second field relief layer 122 is at least initially formed via the same LOCOS process used to form the first field relief layer 116 (e.g., the LOCOS layer 116)—e.g., in an integrated manner. More particularly, as will be described below in FIGS. 2D and 2E, the second field relief layer 122, along with first and second oxide layers 124 separated from and on opposites sides of the second field relief layer 122 (and separated from proximate isolation regions 112), are initially part of a contiguous LOCOS layer (prior to further processing) formed at the same time as the LOCOS layer of the first field relief layer 116. Advantageously, in this manner, two different forms of field relief regions—e.g., a LOCOS layer (e.g., the first field relief layer 116) and a step gate layer (e.g., the second field relief layer 122)—are formed in different LDMOS transistors in the same semiconductor layer 108 via one or more integrated process steps.

As FIG. 1 further shows, LDMOS transistor 103 also includes an n-type drain drift region 130 disposed in the semiconductor layer 108, an n-type source region 142, and an n-type drain region 144 disposed in the drain drift region 130. The second field relief layer 122 is disposed between the source region 142 and the drain region 144, above the second surface 107 of the semiconductor layer 108.

In some examples, although not expressly shown in FIG. 1, the LDMOS transistor 103 can also include a p-type body contact region adjacent the source region 142, both disposed in a deep p-type well (DPWELL). The DPWELL can be disposed in the semiconductor layer 108. A shallow p-type well (SPWELL) (not expressly shown) can also be disposed within the DPWELL. In such examples, the DPWELL can extend partially into the PBL 106. In some examples, the SPWELL has a dopant density higher than that of the semiconductor layer 108. When implemented, the SPWELL provides the same or similar benefits as described above for the SPWELL in the LDMOS transistor 101.

The LDMOS transistor 103 further includes a gate stack. The gate stack includes a gate dielectric layer 133 disposed on a portion of the second surface 107 of the semiconductor layer 108. The gate stack further includes a gate electrode 134 disposed over the gate dielectric layer 133 and at least a portion of the second field relief layer 122. As shown in FIG. 1, the gate electrode 134 extends along the gate dielectric layer 133 and slopes upward in the Z direction along a first tapered (or otherwise substantially straight) sidewall of the second field relief layer 122 proximate to the source region 142 before terminating at an edge along a top non-sloped surface of the second field relief layer 122 (e.g., prior to reaching a second tapered (or otherwise substantially straight) sidewall of the second field relief layer 122 proximate to the drain region 144). In some examples, the edge of the gate electrode 134 above the top non-sloped surface of the second field relief layer 122 may terminate closer to the source region 142 or closer to the drain region 144 as compared to where it is shown terminating in FIG. 1.

In some examples, the gate electrode 134 includes a polysilicon material. In other examples, the gate electrode 134 includes a metal or other suitable material. A channel region may be considered to extend across a portion of the semiconductor layer 108 under the gate electrode 134 between the source region 142 and the drain region 144.

As further shown in FIG. 1, the LDMOS transistor 103 includes sidewall spacer structures 136 along the lateral sides of the gate electrode 134. The sidewall spacer structures 136 in one example include an oxide layer and a nitride layer (not expressly shown). In another example, a nitride-only (or oxide-only) sidewall spacer structure can be implemented.

The LDMOS transistor 103 also includes metal silicide layers 146 that respectively extend over the source region 142, the drain region 144, and the gate electrode 134. In addition, in some examples, the LDMOS transistor 103 includes a nitride etch stop layer (not expressly shown) that extends over portions of the metal silicide layers 146 and the sidewall spacer structures 136. The LDMOS transistor 103 can include a single or multilevel metallization structure (e.g., shared with the LDMOS transistor 101), with a pre-metal dielectric (PMD) layer 150 and conductive metal (e.g., tungsten) contacts 152, terminating on the respective metal silicide layers 146 for the source region 142, the drain region 144, and the gate electrode 134. In some examples, the metal silicide layers 146 can be formed from a Cobalt silicide (CoSiₓ) material.

Referring now to FIGS. 2A-2J, cross-sectional views are shown of an integrated process flow for forming a semiconductor device 200 with at least two LDMOS transistors, an LDMOS transistor 201 and an LDMOS transistor 203, having different forms of field relief layers in accordance with an example of the present disclosure. More particularly, the process flow of FIGS. 2A-2J for the semiconductor device 200 may represent an example of the formation of the semiconductor device 100 of FIG. 1. Accordingly, unless otherwise specified, reference numerals in the 200s in FIGS. 2A-2J correspond to the same layers and structures with reference numerals in the 100s in FIG. 1 (e.g., a semiconductor substrate 202 in FIGS. 2A-2J corresponds to semiconductor substrate 102 in FIG. 1, NBL 204 corresponds to NBL 104, and so on).

FIG. 2A depicts an intermediate stage of formation of the semiconductor device 200. As shown, the semiconductor device 200 includes a p-type semiconductor substrate 202 which may be implemented as a silicon wafer, a silicon-on-sapphire wafer, a silicon carbide wafer, or the like. In some examples, a p-type semiconductor layer 208 is epitaxially grown on the semiconductor substrate 202. Then, n-type dopants or impurities (e.g., phosphorus, etc.) are implanted in the semiconductor layer 208 to form an n-type buried layer (NBL) 204. In other examples, n-type dopants or impurities (e.g., phosphorus, etc.) are introduced to the p-type semiconductor substrate 202, and then a p-type semiconductor layer 208 is epitaxially grown on the semiconductor substrate 202. In other examples, the NBL 204 can be omitted.

FIG. 2A further depicts initial portions of a LOCOS process for forming field relief layers respectively as part of the LDMOS transistor 201 and the LDMOS transistor 203. For example, as shown, a pad oxide layer 210 (e.g., silicon dioxide) is formed on the semiconductor layer 208, e.g., using a thermal oxidation process or a deposition process such as chemical vapor deposition (CVD). In some examples, the pad oxide layer 210 can be about 20 nanometers (nm) in thickness in the Z direction and be referred to as a thin oxide layer.

As further shown in the FIG. 2A example, a plurality of isolation regions 212 are also formed in the semiconductor layer 208 for electrical isolation between the LDMOS transistor 201 and the LDMOS transistor 203 (and between any other adjacent components, not expressly shown). Although FIG. 2A, being a cross-sectional view, illustrates multiple isolation regions 212, the isolation regions 212 may laterally surround each of the LDMOS transistor 201 and the LDMOS transistor 203 in a top-down view (e.g., a layout view). As defined by the spacing of the isolation regions 212, the width (in the X direction) of the region where the LDMOS transistor 201 is to be formed may be relatively smaller than the width (in the X direction) of the region where LDMOS transistor 203 is to be formed.

Next, FIG. 2B depicts a result of a next intermediate formation stage wherein a silicon nitride layer 214 is first deposited across the pad oxide layer 210. The deposited silicon nitride layer 214 can be about 90 nm in thickness in the Z direction. Then, the silicon nitride layer 214 is etched (e.g., a dry etch) using a mask layer (not expressly shown) to form a field relief opening 215 for LDMOS transistor 201 and a field relief opening 217 for LDMOS transistor 203. For each of field relief openings 215 and 217, a portion of the silicon nitride layer 214 resides on each side of the respective openings and extends over a top surface of an adjacent isolation region 212 and adjacent portions of the corresponding pad oxide layer 210. The pad oxide layer 210 in field relief openings 215 and 217 may be removed during the nitride etch exposing a portion of the silicon of the semiconductor layer 208 below the pad oxide layer 210. In some examples, at least a portion of the pad oxide layer 210 may remain in field relief openings 215 and 217 to protect the surface of the silicon during subsequent process steps. While dependent on the transistor types of LDMOS transistors 201 and 203, in some examples, the field relief opening 215 can have a width in the X direction of about 100-300 nm (e.g., about 200 nm) and the field relief opening 217 can have a width in the X direction of about 500-2000 nm (e.g., about 1000 nm).

As shown in FIG. 2C, a thermal oxidation process (e.g., a LOCOS process) is applied at the next intermediate stage of the formation of the semiconductor device 200. The thermal oxidation process is a relatively high-temperature (e.g., about 700 to about 1200 degrees Celsius (° C.)) furnace oxidation that causes the silicon area of the semiconductor layer 208, uncovered by the silicon nitride layer 214 in the field relief openings 215 and 217, to oxidize and form relatively thick layers of silicon dioxide respectively in the field relief openings 215 and 217, e.g., a LOCOS layer 216 and a LOCOS layer 218. As shown, each LOCOS layer is formed partially above and partially below a first surface 205 (e.g., first surface 105 of semiconductor layer 108 in FIG. 1) of the semiconductor layer 208. As an example, a LOCOS thickness (in the Z direction) can be about 100 nm, although the thickness can be dependent on the width of the field relief openings 215 and 217 and the operating parameters of the furnace oxidation. In some examples, the LOCOS layer 218 may be thicker than the LOCOS layer 216. As is typical of a LOCOS process, the portions of the silicon nitride layer 214 on each side of the field relief openings 215 and 217 cause each end of the corresponding LOCOS layers 216 and 218 to exhibit bird's beak profiles.

In some alternative examples, as depicted in FIG. 2C, top portions of one or more of the LOCOS layers 216 and 218 can be etched using one or more patterned layers (e.g., patterned photoresist layers) to define a new top surface and thus to achieve a target thickness (in the Z direction) for the corresponding LOCOS layer. By way of example only, a dashed line 219 represents an etched top surface of the LOCOS layer 218 formed to achieve a target thickness (e.g., about 90 nm assuming the original thickness is about 100 nm) for the LOCOS layer 218—e.g., while the LOCOS layer 216 is covered by a patterned photoresist layer. The LOCOS layer 216 can be etched in a similar manner—e.g., while the LOCOS layer 218 is covered by a patterned photoresist layer.

Next, as shown in FIG. 2D, a mask layer 220 is deposited across semiconductor device 200, then patterned to form openings 221 and 223 over the LOCOS layer 218 of the LDMOS transistor 203. Then, as shown in FIG. 2E, the LOCOS layer 218 is etched (e.g., via a dry etch process, a wet etch process, or some combination thereof) using the mask layer 220 to form an opening 225 (corresponding to opening 221 in the mask layer 220) and an opening 227 (corresponding to opening 223 in the mask layer 220). The openings 225 and 227 extend down to a second surface 207 of the semiconductor layer 208 (corresponding to the second surface 107 of the semiconductor layer 108 in FIG. 1). The mask layer 220 is then removed. As a result, the contiguous LOCOS layer 218 is segmented into a middle oxide portion 222 and two end oxide portions 224. Middle oxide portion 222 includes substantially straight or tapered sidewalls 229, as shown, and represents a step dielectric (e.g., step gate, step oxide) layer-e.g., a second field relief layer 222 corresponding to the second field relief layer 122 of FIG. 1. In some examples, the middle oxide portion 222 includes concave sidewalls—e.g., when an isotropic wet etch process is used to segment contiguous LOCOS layer 218. The two end oxide portions 224 (including the bird's beak profiles of the original LOCOS layer) are also separated from adjacent isolation regions 212, as shown.

In FIG. 2F, prior to removal of the portions of the silicon nitride layer 214, a thin oxide layer 226 (e.g., about 5-10 nm) is formed on the second surface 207 of the semiconductor layer 208 in each of the openings 225 and 227 between the middle oxide portion 222 and the end oxide portions 224 of the original LOCOS layer 218. The thin oxide layer 226 protects the underlying silicon of the semiconductor layer 208 during the nitride strip (removal of the portions of the silicon nitride layer 214).

In a next intermediate stage, as shown in FIG. 2G, an n-type drain drift region 228 is formed in the semiconductor layer 208 below the first field relief layer 216 and an n-type drain drift region 230 is formed in the semiconductor layer 208 below the second field relief layer 222. In some examples, the drain drift regions 228 and 230 can be formed concurrently (or at least contemporaneously or partially concurrently) (e.g., an integrated manner) by implanting phosphorus or other n-type dopants or impurities. In one example, the implantation process can include four implants with a shallow implantation of phosphorous dopants at a low-level implantation energy of approximately 30 to 70 keV and a shallow implantation of arsenic at the same low-level implantation energy, followed by a mid-level implantation of phosphorus or arsenic at approximately 100 to 200 keV and a high energy phosphorus or arsenic implant at approximately 300 to 500 keV, where the implantation dose and energy can vary according to a desired voltage rating of a particular device.

Advantageously, in the present example, formation of the drain drift region 230 occurs after formation of the second field relief layer 222. Otherwise, an additional (drain drift) mask layer would be required to prevent an adverse effect on the doping concentration of the drain drift region 230 when forming the second field relief layer 222. Additionally or alternatively, formation of the second field relief layer 222 after the drain drift region 230 can have an adverse effect on the BV rating of the LDMOS transistor 203.

FIG. 2G also illustrates formation of a p-type buried layer (PBL) 206. For example, the PBL 206 can be formed by implanting boron or other p-type dopants into the p-type semiconductor layer 208 over the NBL 204. In one example, the implantation process implants boron at a dose of about 1×10¹² cm⁻² to 1×10¹³ cm⁻² at an energy of about 400 keV to 3 MeV. In another example, the implantation process can implant indium or other p-type dopants. In certain implementations for low-voltage transistors, the implantation process is a blanket implantation without the use of an implant mask. In another implementation for high-voltage transistors, an implant mask can be used for selective implantation of the PBL 206. In one example, the implantation process can be followed by one or more thermal processes to extend or diffuse the implanted p-type dopants below the drain drift regions 228 and 230 and activate the implanted p-type dopants. In other examples, the formation of PBL 206 can be omitted.

In a next intermediate stage, as shown in FIG. 2H, respective gate stacks for the LDMOS transistors 201 and 203 are formed in an integrated manner. First, gate dielectric layers 231 and 233 are formed in the respective areas where gate electrodes 232 and 234 for the LDMOS transistors 201 and 203 will be formed. In some examples, wherein a pad oxide (e.g., pad oxide layer 210) or other thin oxide (e.g., thin oxide layer 226) is disposed in the target gate dielectric formation areas, such oxide materials may be removed prior to gate dielectric formation, while in other examples, such oxide materials can remain.

Thus, in the FIG. 2H example, a gate dielectric formation process is performed that forms a gate dielectric layer 231 on the first surface 205 of the semiconductor layer 208 and a gate dielectric layer 233 on the second surface 207 of the semiconductor layer 208 in the respective areas where gate electrodes 232 and 234 for the LDMOS transistors 201 and 203 will be formed. Gate dielectric formation can include, in some examples, thermal oxidation or other suitable processing, such as a high temperature furnace operation or a rapid thermal process (RTP). The thickness of the gate dielectric layers 231 and 233 in the Z direction, in one example, is about 3-15 nm for silicon dioxide. Alternatively, a silicon oxynitride gate dielectric layer can be formed that is thicker but with a higher dielectric constant than that of silicon dioxide. In some examples, the gate dielectric layers 231 and 233 may have different thicknesses in the Z direction. In some other examples, the gate dielectric layers 231 and 233 may be deposited using a chemical vapor deposition (CVD) process or an atomic layer deposition (ALD) process.

FIG. 2H also illustrates formation of gate electrodes 232 and 234. In some examples, gate electrode formation can include deposition of a polycrystalline silicon (e.g., polysilicon) layer using one or more silane-based precursors followed by a plasma etch process to define the shape of gate electrodes 232 and 234 and a wet or dry cleaning process to clean exposed surfaces. In other examples, a metal gate or CMOS-based replacement gate electrode process can also be used to form the gate electrodes 232 and 234.

Next, FIG. 2I illustrates formation of sidewall spacer structures 236 along the lateral sides of the gate electrodes 232 and 234. The sidewall spacer structures 236, in some examples, can include an oxide layer and a nitride layer. In one example, an oxide layer and a nitride layer are deposited over the entire wafer surface (not expressly shown), followed by a blanket anisotropic plasma etch process that removes portions of the oxide layer and portions of the nitride layer to form the sidewall spacer structures 236. In another example, nitride-only (or oxide-only) sidewall spacer structures can be implemented.

FIG. 2I further shows formation of source regions 238 and 242 and drain regions 240 and 244 (respectively for the LDMOS transistors 201 and 203) in the semiconductor layer 208 with an n-type dopant(s). More particularly, an integrated implantation process is performed, in some examples, with a relatively shallow source/drain implant that does not penetrate the gate stacks and/or the field relief layers. Moreover, each drain region, in one example, contains an average dopant density at least 100 times that of each drain drift region in which it is implanted. In some examples using an angled implant and/or using additional implants prior to forming the sidewall spacer structures 236, or otherwise due to diffusion, each source region can underlap (not expressly shown) the gate stack. Moreover, in some examples, each drain region can underlap the field relief layer.

Next, FIG. 2J illustrates formation of metal silicide layers 246 that respectively extend over the source regions 238 and 242, the drain regions 240 and 244, and the gate electrodes 232 and 234. In some examples, a metal silicide process includes depositing a metal layer (e.g., Cobalt, not expressly shown), for example, using a blanket deposition process. In some examples, a silicide-blocking layer may be formed prior to depositing the metal layer to define areas exposed to the blanket deposition process. The semiconductor device 200 is then heated to form the metal silicide layers 246 (e.g., Cobalt silicide layer) over the intended areas and unreacted metal is subsequently removed in a wet stripping process.

FIG. 2J also shows formation of a pre-metal dielectric (PMD) layer 250, conductive metal (e.g., tungsten) contacts 252 for the source regions 238 and 242, the drain regions 240 and 244, and the gate electrodes 232 and 234.

Following the process flow of FIGS. 2A-2J, the finished wafer can then be separated (e.g., die singulation) to separate individual semiconductor dies from the starting wafer, and the dies can then be packaged to form integrated circuits or other packaged semiconductor devices.

Referring now to FIG. 3, a semiconductor device 300 is shown. The semiconductor device 300 is illustrated in an example three-dimensional space with a first direction X, a perpendicular (orthogonal) second direction Y, and a third direction Z that is perpendicular (orthogonal) to the respective first and second directions X and Y. Structures or features along any two of these directions are orthogonal to one another.

While semiconductor device 300 is shown as including two LDMOS transistors, e.g., an LDMOS transistor 301 and an LDMOS transistor 303, additional transistors (e.g., LDMOS and/or other transistor types) and/or other components that are not expressly shown may be integrated as part of semiconductor device 300 in various other examples. Also, while the LDMOS transistors in FIG. 3 are illustrated as n-channel LDMOS transistors, in one or more alternative examples, one or more p-channel LDMOS transistors can be formed when n-type regions are substituted by p-type regions and p-type regions are substituted by n-type regions. As used herein, a region, layer, structure, or the like, referred to as being of “a first conductivity type” can be one of a p-type or an n-type, while a region, layer, structure, or the like, referred to as being of “an opposite second conductivity type” can be the other of a p-type or an n-type.

As shown, the semiconductor device 300 includes a semiconductor substrate 302, a first buried layer 304 disposed on the semiconductor substrate 302, a second buried layer 306 disposed on the first buried layer 304, and a semiconductor layer 308 disposed on the second buried layer 306. In some examples, the semiconductor layer 308 can be formed by an epitaxial process, and thus can be referred to as an epitaxial or “epi” layer 308. In the FIG. 3 example, the semiconductor substrate 302 is a p-type substrate, the second buried layer 306 is p-type buried layer (PBL 306), and the semiconductor layer 308 is a p-type semiconductor layer, while the first buried layer 304 is an n-type buried layer (NBL 304). In some examples, the PBL 306 has a dopant concentration greater than the semiconductor layer 308 and can be used to implement reduced surface field (RESURF) principles for safe operating area (SOA) improvement in the semiconductor device 300. While two buried layers, e.g., the NBL 304 and the PBL 306, are shown in FIG. 3, other examples may include one or the other of the buried layers, or no buried layers.

A plurality of isolation regions 312 are disposed in semiconductor layer 308. FIG. 3, being a cross-sectional view, illustrates each of LDMOS transistor 301 and LDMOS transistor 303 are disposed between a pair of the isolation regions 312 with LDMOS transistor 301 and LDMOS transistor 303 separated by a shared isolation region 312. The isolation regions 312 may laterally surround each of LDMOS transistor 301 and LDMOS transistor 303 in a top-down view (e.g., a layout view). In some examples, the isolation regions 312 are STI regions, while in other examples, the isolation regions 312 are deep trench (DT) regions, both STI and DT regions, or some combination thereof. Various other forms of component (e.g., transistor) isolation can be additionally or alternatively implemented in other examples.

As will be further described below in the context of FIGS. 4A-4J, corresponding elements of the LDMOS transistor 301 and the LDMOS transistor 303 (e.g., source regions, drain regions, gate stacks, field relief layers, etc.) are formed in an integrated (e.g., modular) manner. In this context, for example, integrated means that corresponding elements in the LDMOS transistors 301 and 303 are formed at the same (or substantially the same) time using the same process step(s). By way of example, a source region in the LDMOS transistor 301 and a source region in the LDMOS transistor 303 are formed at the same (or substantially the same) time using the same masking and implanting steps, a drain region in the LDMOS transistor 301 and a drain region in the LDMOS transistor 303 are formed at the same (or substantially the same) time using the same masking and implanting steps, and so on. Again, while FIG. 3 depicts only the LDMOS transistors 301 and 303, semiconductor device 300 can include one or more additional transistors and/or other components—wherein one or more corresponding elements of the one or more transistors and/or other components can be similarly formed in an integrated or modular manner along with the LDMOS transistors 301 and 303.

As further shown, LDMOS transistor 301 includes a first field relief layer 316. The first field relief layer 316 is formed via a local oxidation of silicon (LOCOS) process, thus also being referred to herein as a LOCOS layer 316. As will be described below in the context of FIGS. 4A-4J, a second field relief layer 322, which is part of the LDMOS transistor 303 in the form of a step dielectric (step gate) layer, and also referred to herein as a step oxide layer 322, is at least initially formed in an integrated manner via the same LOCOS process used to form the first field relief layer 316 (e.g., the LOCOS layer 316).

LDMOS transistor 301 also includes an n-type drain drift region 328 disposed in the semiconductor layer 308, an n-type source region 338, and an n-type drain region 340 disposed in the drain drift region 328. The first field relief layer 316 is disposed between the source region 338 and the drain region 340, partially above a first surface of the semiconductor layer 308 denoted by a dashed line 305 (also referred to as a first surface 305) and partially below the first surface 305 and in the drain drift region 328.

In some examples, although not expressly shown in FIG. 3, the LDMOS transistor 301 can also include a p-type body contact region adjacent the source region 338, both disposed in a deep p-type well (DPWELL). The DPWELL can be disposed in the semiconductor layer 308. A shallow p-type well (SPWELL) (not expressly shown) can also be disposed within the DPWELL. In such examples, the DPWELL can extend partially into the PBL 306. In some examples, the SPWELL has a dopant density higher than that of the semiconductor layer 308. When implemented, the SPWELL increases a base doping level of the semiconductor layer 308 to suppress a parasitic lateral NPN bipolar transistor formed by n-type source/p-type body region/n-type drain, which may limit high current operation for the LDMOS transistor 301 thus restricting its SOA.

The LDMOS transistor 301 further includes a gate stack. The gate stack includes a gate dielectric layer 331 disposed on a portion of the first surface 305 of the semiconductor layer 308. The gate stack further includes a gate electrode 332 disposed over the gate dielectric layer 331 and at least a portion of the first field relief layer 316. As shown in FIG. 3, the gate electrode 332 extends along the gate dielectric layer 331 and slopes upward in the Z direction along a first bird's beak portion of the first field relief layer 316 proximate to the source region 338 before terminating at an edge along a top non-sloped surface of the first field relief layer 316 (e.g., prior to reaching a second bird's beak portion of the first field relief layer 316 proximate to the drain region 340). In some examples, the edge of the gate electrode 332 above the top non-sloped surface of the first field relief layer 316 may terminate closer to the source region 338 or closer to the drain region 340 as compared to where it is shown terminating in FIG. 3.

In some examples, the gate electrode 332 includes a polysilicon material. In other examples, the gate electrode 332 includes a metal or other suitable material. A channel region may be considered to extend across a portion of the semiconductor layer 308 under the gate electrode 332 between the source region 338 and the drain region 340.

As further shown in FIG. 3, the LDMOS transistor 301 includes sidewall spacer structures 336 along the lateral sides of the gate electrode 332. The sidewall spacer structures 336 in one example include an oxide layer and a nitride layer (not expressly shown). In another example, a nitride-only (or oxide-only) sidewall spacer structure can be implemented.

The LDMOS transistor 301 also includes metal silicide layers 346 that respectively extend over the source region 338, the drain region 340, and the gate electrode 332. In addition, in some examples, the LDMOS transistor 301 includes a nitride etch stop layer (not expressly shown) that extends over portions of the metal silicide layers 346 and the sidewall spacer structures 336. The LDMOS transistor 301 can include a single or multilevel metallization structure (e.g., shared with the LDMOS transistor 303), with a pre-metal dielectric (PMD) layer 350 and conductive metal (e.g., tungsten) contacts 352, terminating on the respective metal silicide layers 346 for the source region 338, the drain region 340, and the gate electrode 332. In some examples, the metal silicide layers 346 can be formed from a Cobalt silicide (CoSiₓ) material.

With reference now to the LDMOS transistor 303, a second field relief layer 322 (e.g., also referred to as a step dielectric layer 322, a step gate layer 322, or a step oxide layer 322) is disposed, as shown in FIG. 3, on a second surface of the semiconductor layer 308 denoted by a dashed line 307 (also referred to as a second surface 307). The second surface 307 of the semiconductor layer 308 is recessed by a depth D₂ (in the Z direction) relative to the first surface 305 of the semiconductor layer 308. In some examples, the depth D₂ is in a range of approximately 20-100 nanometers (nm), e.g., approximately 50 nm.

As described above, and as will be further described below in the context of FIGS. 4A-4J, the second field relief layer 322 is at least initially formed via the same LOCOS process used to form the first field relief layer 316 (e.g., the LOCOS layer 316) e.g., in an integrated manner. More particularly, as will be described below in FIGS. 4D and 4E, the second field relief layer 322, along with first and second oxide layers 324 separated from and on opposites sides of the second field relief layer 322 (and abutting proximate isolation regions 312), are initially part of a contiguous LOCOS layer (prior to further processing) formed at the same time as the LOCOS layer of the first field relief layer 316. Advantageously, in this manner, two different forms of field relief regions—e.g., a LOCOS layer (e.g., the first field relief layer 316) and a step gate layer (e.g., the second field relief layer 322)—are formed in different LDMOS transistors in the same semiconductor layer 308 via one or more integrated process steps.

As FIG. 3 further shows, LDMOS transistor 303 also includes an n-type drain drift region 330 disposed in the semiconductor layer 308, an n-type source region 342, and an n-type drain region 344 disposed in the drain drift region 330. The second field relief layer 322 is disposed between the source region 342 and the drain region 344, above the second surface 307 of the semiconductor layer 308.

In some examples, although not expressly shown in FIG. 3, the LDMOS transistor 303 can also include a p-type body contact region adjacent the source region 342, both disposed in a deep p-type well (DPWELL). The DPWELL can be disposed in the semiconductor layer 308. A shallow p-type well (SPWELL) (not expressly shown) can also be disposed within the DPWELL. In such examples, the DPWELL can extend partially into the PBL 306. In some examples, the SPWELL has a dopant density higher than that of the semiconductor layer 308. When implemented, the SPWELL provides the same or similar benefits as described above for the SPWELL in the LDMOS transistor 301.

The LDMOS transistor 303 further includes a gate stack. The gate stack includes a gate dielectric layer 333 disposed on a portion of the second surface 307 of the semiconductor layer 308. The gate stack further includes a gate electrode 334 disposed over the gate dielectric layer 333 and at least a portion of the second field relief layer 322. As shown in FIG. 3, the gate electrode 334 extends along the gate dielectric layer 333 and slopes upward in the Z direction along a first tapered (or otherwise substantially straight) sidewall of the second field relief layer 322 proximate to the source region 342 before terminating at an edge along a top non-sloped surface of the second field relief layer 322 (e.g., prior to reaching a second tapered (or otherwise substantially straight) sidewall of the second field relief layer 322 proximate to the drain region 344). In some examples, the edge of the gate electrode 334 above the top non-sloped surface of the second field relief layer 322 may terminate closer to the source region 342 or closer to the drain region 344 as compared to where it is shown terminating in FIG. 3.

In some examples, the gate electrode 334 includes a polysilicon material. In other examples, the gate electrode 334 includes a metal or other suitable material. A channel region may be considered to extend across a portion of the semiconductor layer 308 under the gate electrode 334 between the source region 342 and the drain region 344.

As further shown in FIG. 3, the LDMOS transistor 303 includes sidewall spacer structures 336 along the lateral sides of the gate electrode 334. The sidewall spacer structures 336 in one example include an oxide layer and a nitride layer (not expressly shown). In another example, a nitride-only (or oxide-only) sidewall spacer structure can be implemented.

The LDMOS transistor 303 also includes metal silicide layers 346 that respectively extend over the source region 342, the drain region 344, and the gate electrode 334. In addition, in some examples, the LDMOS transistor 303 includes a nitride etch stop layer (not expressly shown) that extends over portions of the metal silicide layers 346 and the sidewall spacer structures 336. The LDMOS transistor 303 can include a single or multilevel metallization structure (e.g., shared with the LDMOS transistor 301), with a pre-metal dielectric (PMD) layer 350 and conductive metal (e.g., tungsten) contacts 352, terminating on the respective metal silicide layers 346 for the source region 342, the drain region 344, and the gate electrode 334. In some examples, the metal silicide layers 346 can be formed from a Cobalt silicide (CoSiₓ) material.

Referring now to FIGS. 4A-4J, cross-sectional views are shown of an integrated process flow for forming a semiconductor device 400 with at least two LDMOS transistors, an LDMOS transistor 401 and an LDMOS transistor 403, having different forms of field relief layers in accordance with an example of the present disclosure. More particularly, the process flow of FIGS. 4A-4J for the semiconductor device 400 may represent an example of the formation of the semiconductor device 300 of FIG. 3. Accordingly, unless otherwise specified, reference numerals in the 400s in FIGS. 4A-4J correspond to the same layers and structures with reference numerals in the 300s in FIG. 3 (e.g., a semiconductor substrate 402 in FIGS. 4A-4J corresponds to semiconductor substrate 302 in FIG. 3, NBL 404 corresponds to NBL 304, and so on).

FIG. 4A depicts an intermediate stage of formation of the semiconductor device 400. As shown, the semiconductor device 400 includes a p-type semiconductor substrate 402 which may be implemented as a silicon wafer, a silicon-on-sapphire wafer, a silicon carbide wafer, or the like. In some examples, a p-type semiconductor layer 408 is epitaxially grown on the semiconductor substrate 402. Then, n-type dopants or impurities (e.g., phosphorus, etc.) are implanted in the semiconductor layer 408 to form an n-type buried layer (NBL) 404. In other examples, n-type dopants or impurities (e.g., phosphorus, etc.) are introduced to the p-type semiconductor substrate 402, and then a p-type semiconductor layer 408 is epitaxially grown on the semiconductor substrate 402. In other examples, the NBL 404 can be omitted.

FIG. 4A further depicts initial portions of a LOCOS process for forming field relief layers respectively as part of the LDMOS transistor 401 and the LDMOS transistor 403. For example, as shown, a pad oxide layer 410 (e.g., silicon dioxide) is formed on the semiconductor layer 408, e.g., using a thermal oxidation process or a deposition process such as chemical vapor deposition (CVD). In some examples, the pad oxide layer 410 can be about 20 nanometers (nm) in thickness in the Z direction and be referred to as a thin oxide layer.

As further shown in the FIG. 4A example, a plurality of isolation regions 412 are also formed in the semiconductor layer 408 for electrical isolation between the LDMOS transistor 401 and the LDMOS transistor 403 (and between any other adjacent components, not expressly shown). Although FIG. 4A, being a cross-sectional view, illustrates multiple isolation regions 412, the isolation regions 412 may laterally surround each of the LDMOS transistor 401 and the LDMOS transistor 403 in a top-down view (e.g., a layout view). As defined by the spacing of the isolation regions 412, the width (in the X direction) of the region where the LDMOS transistor 401 is to be formed may be relatively smaller than the width (in the X direction) of the region where LDMOS transistor 403 is to be formed.

Next, FIG. 4B depicts a result of a next intermediate formation stage wherein a silicon nitride layer 414 is first deposited across the pad oxide layer 410. The deposited silicon nitride layer 411 can be about 90 nm in thickness in the Z direction. Then, the silicon nitride layer 414 is etched (e.g., a dry etch) using a mask layer (not expressly shown) to form a field relief opening 415 for LDMOS transistor 401 and a field relief opening 417 for LDMOS transistor 403. For each of field relief openings 415 and 417, a portion of the silicon nitride layer 414 resides on each side of the respective openings, as shown. In the case of the field relief opening 417, the corresponding portions of the silicon nitride layer 414 extend partially over a top surface of adjacent isolation regions 412, as shown. This differs from the portions of the silicon nitride layer 214 corresponding to the field relief opening 217 in FIG. 2B for semiconductor device 200—which will result in different profiles for two end oxide portions 424 (as compared to the two end oxide portions 224 in FIG. 2) to be described below. The pad oxide layer 410 in field relief openings 415 and 417 may be removed during the nitride etch exposing a portion of the silicon of the semiconductor layer 408 below the pad oxide layer 410. In some examples, at least a portion of the pad oxide layer 410 may remain in field relief openings 415 and 417 to protect the surface of the silicon during subsequent process steps. While dependent on the transistor types of LDMOS transistors 401 and 403, in some examples, the field relief opening 415 can have a width in the X direction of about 100-300 nm (e.g., about 200 nm) and the field relief opening 417 can have a width in the X direction of about 500-2000 nm (e.g., about 1000 nm).

As shown in FIG. 4C, a thermal oxidation process (e.g., a LOCOS process) is applied at the next intermediate stage of the formation of the semiconductor device 400. The thermal oxidation process is a relatively high-temperature (e.g., about 700 to about 1200 degrees Celsius (° C.)) furnace oxidation that causes the silicon area of the semiconductor layer 408, uncovered by the silicon nitride layer 414 in the field relief openings 415 and 417, to oxidize and form relatively thick layers of silicon dioxide respectively in the field relief openings 415 and 417, e.g., a LOCOS layer 416 and a LOCOS layer 418. As shown, each LOCOS layer is formed partially above and partially below a first surface 405 (e.g., first surface 305 of semiconductor layer 308 in FIG. 3) of the semiconductor layer 408. As an example, a LOCOS thickness (in the Z direction) can be about 100 nm, although the thickness can be dependent on the width of the field relief openings 415 and 417 and the operating parameters of the furnace oxidation. In some examples, the LOCOS layer 418 may be thicker than the LOCOS layer 416. The portions of the silicon nitride layer 414 on each side of the field relief opening 415 cause each end of the LOCOS layer 416 to exhibit bird's beak profiles. However, due to the formation of the portions of the silicon nitride layer 414 on each side of the field relief opening 417—e.g., only partially over top surfaces of the adjacent isolation regions 412, but not extending over the pad oxide layer 410—no bird's beak profiles are formed on the ends of the LOCOS layer 418. Rather, the end profiles of the LOCOS layer 418 are substantially straight in the Z direction and abut adjacent isolation regions 412, as shown.

In some alternative examples, as depicted in FIG. 4C, top portions of one or more of the LOCOS layers 416 and 418 can be etched using one or more patterned layers (e.g., patterned photoresist layers) to define a new top surface and thus to achieve a target thickness (in the Z direction) for the corresponding LOCOS layer. By way of example only, a dashed line 419 represents an etched top surface of the LOCOS layer 418 formed to achieve a target thickness (e.g., about 90 nm assuming the original thickness is about 100 nm) for the LOCOS layer 418—e.g., while the LOCOS layer 416 is covered by a patterned photoresist layer. The LOCOS layer 416 can be etched in a similar manner e.g., while the LOCOS layer 418 is covered by a patterned photoresist layer.

Next, as shown in FIG. 4D, a mask layer 420 is deposited across semiconductor device 400, then patterned to form openings 421 and 423 over the LOCOS layer 418 of the LDMOS transistor 403. Then, as shown in FIG. 4E, the LOCOS layer 418 is etched (e.g., via a dry etch process, a wet etch process, or some combination thereof) using the mask layer 420 to form an opening 425 (corresponding to opening 421 in the mask layer 420) and an opening 427 (corresponding to opening 423 in the mask layer 420). The openings 425 and 427 extend down to a second surface 407 of the semiconductor layer 408 (corresponding to the second surface 307 of the semiconductor layer 308 in FIG. 3). The mask layer 420 is then removed. As a result, the contiguous LOCOS layer 418 is segmented into a middle oxide portion 422 and two end oxide portions 424. Middle oxide portion 422 includes substantially straight or tapered sidewalls 429, as shown, and represents a step dielectric (e.g., step gate, step oxide) layer-e.g., a second field relief layer 422 corresponding to the second field relief layer 322 of FIG. 3. In some examples, the middle oxide portion 422 includes concave sidewalls—e.g., when an isotropic wet etch process is used to segment contiguous LOCOS layer 418. The two end oxide portions 424 abut adjacent isolation regions 412, as shown. One advantage of the location of the two end oxide portions 422 relative to the adjacent isolation regions 412 is to avoid etching the adjacent isolation regions 412 during the wet etch used to form the opening 427.

In FIG. 4F, prior to removal of the portions of the silicon nitride layer 414, a thin oxide layer 426 (e.g., about 5-10 nm) is formed on the surface of the semiconductor layer 408 in each of the openings 425 and 427 between the middle oxide portion 422 and the end oxide portions 424 of the original LOCOS layer 418. The thin oxide layer 426 protects the underlying silicon of the semiconductor layer 408 during the nitride strip (removal of the portions of the silicon nitride layer 414).

In a next intermediate stage, as shown in FIG. 4G, an n-type drain drift region 428 is formed in the semiconductor layer 408 below the first field relief layer 416 and an n-type drain drift region 430 is formed in the semiconductor layer 408 below the second field relief layer 422. In some examples, the drain drift regions 428 and 430 can be formed concurrently (or at least contemporaneously or partially concurrently) (e.g., an integrated manner) by implanting phosphorus or other n-type dopants or impurities. In one example, the implantation process can include four implants with a shallow implantation of phosphorous dopants at a low-level implantation energy of approximately 30 to 70 keV and a shallow implantation of arsenic at the same low-level implantation energy, followed by a mid-level implantation of phosphorus or arsenic at approximately 100 to 200 keV and a high energy phosphorus or arsenic implant at approximately 300 to 500 keV, where the implantation dose and energy can vary according to a desired voltage rating of a particular device.

Advantageously, in the present example, formation of the drain drift region 430 occurs after formation of the second field relief layer 422. Otherwise, an additional (drain drift) mask layer would be required to prevent an adverse effect on the doping concentration of the drain drift region 430 when forming the second field relief layer 422. Additionally or alternatively, formation of the second field relief layer 422 after the drain drift region 430 can have an adverse effect on the BV rating of the LDMOS transistor 403.

FIG. 4G also illustrates formation of a p-type buried layer (PBL) 406. For example, the PBL 406 can be formed by implanting boron or other p-type dopants into the p-type semiconductor layer 408 over the NBL 404. In one example, the implantation process implants boron at a dose of about 1×10¹² cm⁻² to 1×10¹³ cm⁻² at an energy of about 400 keV to 3 MeV. In another example, the implantation process can implant indium or other p-type dopants. In certain implementations for low-voltage transistors, the implantation process is a blanket implantation without the use of an implant mask. In another implementation for high-voltage transistors, an implant mask can be used for selective implantation of the PBL 406. In one example, the implantation process can be followed by one or more thermal processes to extend or diffuse the implanted p-type dopants below the drain drift regions 428 and 430 and activate the implanted p-type dopants. In other examples, the formation of PBL 406 can be omitted.

In a next intermediate stage, as shown in FIG. 4H, respective gate stacks for the LDMOS transistors 401 and 403 are formed in an integrated manner. First, gate dielectric layers 431 and 433 are formed in the respective areas where gate electrodes 432 and 434 for the LDMOS transistors 401 and 403 will be formed. In some examples, wherein a pad oxide (e.g., pad oxide layer 410) or other thin oxide (e.g., thin oxide layer 426) is disposed in the target gate dielectric formation areas, such oxide materials may be removed prior to gate dielectric formation, while in other examples, such oxide materials can remain.

Thus, in the FIG. 4H example, a gate dielectric formation process is performed that forms a gate dielectric layer 431 on the first surface 405 of the semiconductor layer 408 and a gate dielectric layer 433 on the second surface 407 of the semiconductor layer 408 in the respective areas where gate electrodes 432 and 434 for the LDMOS transistors 401 and 403 will be formed. Gate dielectric formation can include, in some examples, thermal oxidation or other suitable processing, such as a high temperature furnace operation or a rapid thermal process (RTP). The thickness of the gate dielectric layers 431 and 433 in the Z direction, in one example, is about 3-15 nm for silicon dioxide. Alternatively, a silicon oxynitride gate dielectric layer can be formed that is thicker but with a higher dielectric constant than that of silicon dioxide. In some examples, the gate dielectric layers 431 and 433 may have different thicknesses in the Z direction. In some other examples, the gate dielectric layers 431 and 433 may be deposited using a chemical vapor deposition (CVD) process or an atomic layer deposition (ALD) process.

FIG. 4H also illustrates formation of gate electrodes 432 and 434. In some examples, gate electrode formation can include deposition of a polycrystalline silicon (e.g., polysilicon) layer using one or more silane-based precursors followed by a plasma etch process to define the shape of gate electrodes 432 and 434 and a wet or dry cleaning process to clean exposed surfaces. In other examples, a metal gate or CMOS-based replacement gate electrode process can also be used to form the gate electrodes 432 and 434.

Next, FIG. 4I illustrates formation of sidewall spacer structures 436 along the lateral sides of the gate electrodes 432 and 434. The sidewall spacer structures 436, in some examples, can include an oxide layer and a nitride layer. In one example, an oxide layer and a nitride layer are deposited over the entire wafer surface (not expressly shown), followed by a blanket anisotropic plasma etch process that removes portions of the oxide layer and portions of the nitride layer to form the sidewall spacer structures 436. In another example, nitride-only (or oxide-only) sidewall spacer structures can be implemented.

FIG. 4I further shows formation of source regions 438 and 442 and drain regions 440 and 444 (respectively for the LDMOS transistors 401 and 403) in the semiconductor layer 408 with an n-type dopant(s). More particularly, an integrated implantation process is performed, in some examples, with a relatively shallow source/drain implant that does not penetrate the gate stacks and/or the field relief layers. Moreover, each drain region, in one example, contains an average dopant density at least 100 times that of each drain drift region in which it is implanted. In some examples using an angled implant and/or using additional implants prior to forming the sidewall spacer structures 436, or otherwise due to diffusion, each source region can underlap (not expressly shown) the gate stack. Moreover, in some examples, each drain region can underlap the field relief layer.

Next, FIG. 4J illustrates formation of metal silicide layers 446 that respectively extend over the source regions 438 and 442, the drain regions 440 and 444, and the gate electrodes 432 and 434. In some examples, a metal silicide process includes depositing a metal layer (e.g., Cobalt, not expressly shown), for example, using a blanket deposition process. In some examples, a silicide-blocking layer may be formed prior to depositing the metal layer to define areas exposed to the blanket deposition process. The semiconductor device 400 is then heated to form the metal silicide layers 446 (e.g., Cobalt silicide layer) over the intended areas and unreacted metal is subsequently removed in a wet stripping process.

FIG. 4J also shows formation of a pre-metal dielectric (PMD) layer 450, conductive metal (e.g., tungsten) contacts 452 for the source regions 438 and 442, the drain regions 440 and 444, and the gate electrodes 432 and 434.

Following the process flow of FIGS. 4A-4J, the finished wafer can then be separated (e.g., die singulation) to separate individual semiconductor dies from the starting wafer, and the dies can then be packaged to form integrated circuits or other packaged semiconductor devices.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A method of fabricating a semiconductor device, comprising:
forming a first field relief layer on a first surface of a semiconductor layer, the first field relief layer being a step-oxide field relief layer formed from a first oxide layer, the first oxide layer being formed via a local oxidation of silicon (LOCOS) process; and
forming a first drain region, a first source region, and a first gate stack, the first drain region being proximate to a first end of the first field relief layer, the first source region being proximate to a second end of the first field relief layer, and the first gate stack being between the first drain region and the first source region and partially over the first field relief layer.

2. The method of claim 1, further comprising:
forming a second field relief layer on a second surface of the semiconductor layer, the second field relief layer being formed concurrently with the first oxide layer via the LOCOS process; and
forming a second drain region, a second source region, and a second gate stack, the second drain region being proximate to a first end of the second field relief layer, the second source region being proximate to a second end of the second field relief layer, and the second gate stack being between the second drain region and the second source region and partially over the second field relief layer.

3. The method of claim 2, wherein the first surface of the semiconductor layer is recessed relative to the second surface of the semiconductor layer as a result of the LOCOS process.

4. The method of claim 2, wherein the first source region, the first drain region, the first gate stack, and the first field relief layer are formed in a recessed region, and the second source region, the second drain region, the second gate stack, and the second field relief layer are formed outside the recessed region.

5. The method of claim 1, wherein forming the first field relief layer further comprises:
forming a thin oxide layer, relative to a thickness of the first oxide layer, on a second surface of the semiconductor layer, the thin oxide layer being between a pair of isolation regions;
forming a first portion and a second portion of a nitride layer, the first portion of the nitride layer being formed over a first one of the pair of isolation regions and a first portion of the thin oxide layer, and the second portion of the nitride layer being formed over a second one of the pair of isolation regions and a second portion of the thin oxide layer, wherein an opening is formed between the first portion of the nitride layer and the second portion of the nitride layer; and
thermally growing the first oxide layer in the opening, the first oxide layer extending to the first surface of the semiconductor layer, wherein the first surface of the semiconductor layer being recessed relative to the second surface of the semiconductor layer as a result of the LOCOS process.

6. The method of claim 5, wherein forming the first field relief layer further comprises:
etching the first oxide layer substantially to the first surface of the semiconductor layer, using a first mask, to form a middle portion of the first oxide layer and two end portions of the first oxide layer separated from and on opposite sides of the middle portion, the middle portion being the first field relief layer.

7. The method of claim 6, wherein the two end portions of the first oxide layer have respective bird's beak profiles separated from respective ones of the pair of isolation regions.

8. The method of claim 1, wherein forming the first field relief layer further comprises:
forming a thin oxide layer, relative to a thickness of the first oxide layer, on a second surface of the semiconductor layer, the thin oxide layer being between a pair of isolation regions;
forming a first portion and a second portion of a nitride layer, the first portion of the nitride layer being formed partially over a first one of the pair of isolation regions, and the second portion of the nitride layer being formed partially over a second one of the pair of isolation regions, wherein an opening is formed between the first portion of the nitride layer and the second portion of the nitride layer; and
thermally growing the first oxide layer in the opening, the first oxide layer extending to the first surface of the semiconductor layer, wherein the first surface of the semiconductor layer is recessed relative to the second surface of the semiconductor layer as a result of the LOCOS process.

9. The method of claim 8, wherein forming the first field relief layer further comprises:
etching the first oxide layer substantially to the first surface of the semiconductor layer, using a first mask, to form a middle portion of the first oxide layer and two end portions of the first oxide layer separated from and on opposite sides of the middle portion, the middle portion being the first field relief layer.

10. The method of claim 9, wherein the two end portions of the first oxide layer abut respective ones of the pair of isolation regions.

11. A method of fabricating a semiconductor device, comprising:
forming a first transistor including: (i) a first field relief layer on a first surface of a semiconductor layer, the first field relief layer being a step-oxide field relief layer formed from a first local oxidation of silicon (LOCOS) layer, (ii) a first drain region, (iii) a first source region, and (iv) a first gate stack, the first drain region being proximate to a first end of the first field relief layer, the first source region being proximate to a second end of the first field relief layer, and the first gate stack being between the first drain region and the first source region and partially over the first field relief layer; and
forming a second transistor including: (i) a second field relief layer on a second surface of the semiconductor layer, the second field relief layer being a second LOCOS field relief layer formed via the same LOCOS process as the first LOCOS layer, (ii) a second drain region, (iii) a second source region, and (iv) a second gate stack, the second drain region being proximate to a first end of the second field relief layer, the second source region being proximate to a second end of the second field relief layer, and the second gate stack being between the second drain region and the second source region and partially over the second field relief layer.

12. The method of claim 11, wherein the first surface of the semiconductor layer is recessed relative to the second surface of the semiconductor layer.

13. The method of claim 11, wherein the first source region, the first drain region, the first gate stack, and the first field relief layer are formed in a recessed region, and the second source region, the second drain region, the second gate stack, and the second field relief layer are formed outside the recessed region.

14. A semiconductor device, comprising:
a semiconductor layer;
a first transistor disposed in a first region of the semiconductor layer, the first transistor including:
a first field relief layer;
a first drain region disposed proximate to a first end of the first field relief layer;
a first source region disposed proximate to a second end of the first field relief layer; and
a first gate stack including a first gate electrode and a first gate dielectric layer, the first gate stack disposed between the first drain region and the first source region and partially over the first field relief layer; and
a second transistor disposed in a second region of the semiconductor layer different than the first region, the second transistor including a second gate dielectric layer, the first gate dielectric layer being recessed relative to the second gate dielectric layer.

15. The semiconductor device of claim 14, wherein the second transistor includes:
a second field relief layer having a first portion disposed partially in the semiconductor layer and a second portion disposed partially above the semiconductor layer;
a second drain region disposed proximate to a first end of the second field relief layer;
a second source region disposed proximate to a second end of the second field relief layer; and
a second gate stack including a second gate electrode and the second gate dielectric layer, the second gate stack disposed between the second drain region and the second source region and partially over the second field relief layer.

16. The semiconductor device of claim 14, further comprising:
a pair of isolation regions including a first isolation region disposed on a first end of the first region and a second isolation region disposed on a second end of the first region.

17. The semiconductor device of claim 16, wherein the first transistor includes:
a first oxide region separated from the first isolation region and the first end of the first field relief layer; and
a second oxide region separated from the second isolation region and the second end of the first field relief layer.

18. The semiconductor device of claim 16, wherein the first transistor includes:
a first oxide region abutting the first isolation region and separated from the first end of the first field relief layer; and
a second oxide region abutting the second isolation region and separated from the second end of the first field relief layer.

19. The semiconductor device of claim 15, wherein the first field relief layer includes one or more substantially straight sidewalls, and the second field relief layer includes opposing ends having bird's beak profiles.

20. The semiconductor device of claim 15, wherein the first field relief layer and the second field relief layer are at least partially concurrently formed.

21. The semiconductor device of claim 14, wherein the first field relief layer has a width, defined along a direction between the first source region and the first drain region, less than a width of the first region.

22. The semiconductor device of claim 14, wherein the first field relief layer is a step-oxide field relief layer.
